(19) United States
(12) Patent Application Publication
(10) Pub. No.: US 2024/0072730 A1
(43) Pub. Date: Feb. 29, 2024

(54) Slatted Cathode for Frequency Agility of MILO HPM Source

(71) Applicant: UNM Rainforest Innovations, Albuquerque, NM (US)

(72) Inventors: Salvador Portillo, Albuquerque, NM (US); Ahmed Elshafiey, Albuquerque, NM (US)

(73) Assignee: UNM Rainforest Innovations, Albuquerque, NM (US)

(21) Appl. No.: 18/087,120

(22) Filed: Dec. 22, 2022

Related U.S. Application Data
(60) Provisional application No. 63/293,371, filed on Dec. 23, 2021.

(51) Int. Cl. H03B 9/10

(52) U.S. Cl. CPC H03B 9/10

(57) ABSTRACT

A magnetically insulated line oscillator (MILO) that is a high power microwave (HPM) source. A cross field device with a plurality of azimuthally extending spaced apart slats.

### RELATED APPLICATIONS

This application claims priority to U.S. Provisional Application No. 63/293,371, filed on Dec. 23, 2021, which is incorporated herein in its entirety.

### STATEMENT REGARDING FEDERALLY SPONSORED RESEARCH & DEVELOPMENT

This invention was made with government support under N00014-19-1-2155 awarded by the Office Of Naval Research and under FA9550-19-1-0225 awarded by the Air Force Office of Scientific Research. The government has certain rights in the invention.

### INCORPORATION BY REFERENCE OF MATERIAL SUBMITTED ON A COMPACT DISC

Not applicable.

### BACKGROUND BACKGROUND OF THE INVENTION

A Magnetically Insulated Line Oscillator (MILO) is a High Power Microwave (HPM) source that is in active development worldwide. Its purpose is to generate HPM at sufficiently high energies, that is for long pulses. The MILO has struggled to achieve long pulses due to neutral desorption from the cathodes these neutrals, are ionized leading to the neutralization of the beam which in turn results in impedance collapse and ends the production of electromagnetic radiation.

This problem has plagued the HPM industry for years if not decades and has not been resolved on the MILO. As shown in FIG. 1. A typical MILO 100 is comprised of coaxial cylinders. The outer cylinder 110 is the anode and the inner cylinder is an azimuthally continuous cathode 120 which produces electrons due to applied voltage (E field) and is vacuum 150 terminated into a beam dump 152. FIG. 2 shows the electrical output of MILO 100.

The anode contains cavities in the form of a slow-wave structure. The anode and cathode operate in a high vacuum, in the order of 10E-6 Torr. The electrons from the cathode are in such a large number that they produce a magnetic field. This happens when the number of electrons reaches a critical current, Icritical. This magnetic field serves to insulate the electron flow and keep it from shorting out. This magnetic field is azimuthal which is perpendicular to the radial electric field and this leads to a drift of the electrons in the ExB direction, however, due to the slow-wave structures 130-134 the electron sheath current is disturbed enough near the cavities and electrons overcome the self-insulation and go into the cavities feeding the standing waves present in the cavity.

The critical point is that this process is disturbed if ions are present in the region between the anode and cathode, we call this the AK gap. Ions in the AK gap neutralize the beam, which means the current in the AK gap is insufficient to maintain the magnetic insulation, that is the current falls below Icritical. When this happens the electrons no longer ‘feed’ the cavities via spokes going into the cavities and instead just short or go directly to the Anode. This is called impedance collapse.

The neutrals desorbed from the cathode (and other structures such as the anode) are ionized by the incident electron beam. These ions lead to radiation stoppage.

What is desired is a very long pulse of radiation. Ions in the AK gap prevent long pulses. That is neutrals desorbed from the cathode prevent long pulses.

The number of neutrals (hydrocarbons and other neutral atoms, such as N2, etc) is dependent on cleanliness and treatment of the cathode but this number of neutrals is also dependent on the amount of surface area of the cathode. The larger the area of the cathode the more neutrals it has and the more neutrals it can desorb into the AK gap.

Additionally, the neutrals make it so that the following pulse is unable to propagate is these neutrals will also affect following pulses. This means that the neutrals in the AK gap after the first pulse cannot be easily removed by the vacuum system.

The pulse repetition of a MILO is limited by the vacuum in the system. Neutrals in the AK gap are hard to remove and so the vacuum is degraded. All crossed field devices that operate as HPM sources or electromagnetic radiators that employ a slow wave structure use cavities 140-142 as resonant structures. A crossed field device is one that has two fields, E and B are perpendicularly applied to the system. Some crossed field devices include the magnetron, the MILO (Magnetic Insulated Line Oscillator), the Travelling Wave Tube (TWT) to name three (this list is not exhaustive there are others such as the Reltron, crossed field amplifier or CFA, etc).

The applied field leading to the Electric field typically produces and/or accelerates the electrons. There is also an applied field or a self-magnetic generated field in the case of the MILO that is perpendicular to the electric field leading to crossed fields leading to the behavior needed for synchronism to occur.

Cavities are used to store the initial electromagnetic energy that is started at the onset of electron emission or fed via some external source, this electromagnetic energy is usually in the cavity as standing electromagnetic waves. Cavities are typically (but not necessarily) in the anode electrode part of the system.

The electrons produced by the cathode of the source interact with the cavities and those electrons feed or give energy to the standing waves present in the cavities. This interaction occurs when the drift velocity of the incident electrons is the same as the phase velocity of the electromagnetic wave—that is both quantities are in synchronism.

The standing waves in the cavities are defined by the size and shape of the cavities. Resonators may be used to support certain frequencies. The frequencies are dependent on the shape (size) of the cavity.

All resonators, especially electrical ones, are comprised of a resistive, capacitive, and inductive part. Because of this, the resonator or cavity can be described by an L-C-R (Inductive-Capacitive-Resistive) circuit

### SUMMARY OF THE INVENTION

In one embodiment, the present invention provides a magnetically insulated line oscillator (MILO) that is a high power microwave (HPM) source.

In other embodiments, MILO is a coaxial device, consisting of an inner conductor and an outer conductor. The outer conductor is comprised of cavities and vanes (the Anode) and the inner conductor is mostly an electrode that emits electrons (a Cathode). The inner conductor is vacuum terminated into a beam dump (there is a vacuum gap between cathode and beam dump just like between cathode and anode). The beam dump is at the potential of the anode. The cathode is a solid azimuthally continuous (360 degree) cylinder-like structure.

In other embodiments, MILO is a crossed field device, this means that it operates with an applied high voltage, typically in the 100's of KiloVolts (albeit not mandatory) which leads to a potential difference between the inner and outer conductors such that electrons are emitted from the cathode due to the large electric fields between the anode and cathode.

In other embodiments, the present invention provides a magnetically insulated line oscillator wherein the electric field is radial.

In other embodiments, the present invention provides a magnetically insulated line oscillator wherein large currents initiated by the pulse of applied high voltage can lead to sufficiently large current producing a self-insulation of the electron current between the anode and cathode (AK) gap. This magnetic insulation is due to the azimuthal magnetic field generated by the electrons themselves-self magnetically insulated.

In other embodiments, the present invention provides a magnetically insulated line oscillator wherein the applied Electric Field (E) and the azimuthal magnetic field (B) lead to a force that results in motion of the electrons axially. It is called the ExB drift (E cross B drift).

In other embodiments, the present invention provides a magnetically insulated line oscillator wherein the anode has cavities and the electric field is not uniform moving in an axial direction. These cavities can contain Electromagnetic Energy (EM) started when the electrons are the first field/explosively emitted from the cathode. These cavities, with the started Electromagnetic (EM) energy, can contain more EM energy if it is ‘fed’ somehow. This happens when the electrons from magnetically insulated sheath current are made to go into the cavities (due to the non-uniform axial field, due to the change in the shape of the anode, due to the cavities). When this happens the electron drift velocity is in synchronism with the electromagnetic wave (phase velocity) in the cavities. This then leads to an increase in electromagnetic energy. This electromagnetic energy is fixed at some frequency-dependent on the cavity and the synchronism of the electron flow. The frequencies in the MILO are fixed to the resonant frequency of the cavity and the 2nd and 3rd harmonic frequencies of said cavity.

In other embodiments, the present invention provides a magnetically insulated line oscillator wherein the MILO has multiple frequencies apart from the resonant frequency and 2nd,3rd, 4th, and higher harmonics. Up to this point, a MILO is essentially a single frequency, the fundamental, with the harmonics at much lower energy content.

In other embodiments, the present invention concerns a magnetically insulated line oscillator (MILO) that is a high power microwave (HPM) source.

In other embodiments, the present invention concerns a magnetically insulated line oscillator (MILO) comprising: a coaxial device, consisting of an inner conductor and an outer conductor; the outer conductor is comprised of cavities and vanes (the Anode) and the inner conductor is mostly an electrode that emits electrons (a Cathode).

In other embodiments, the present wherein the inner conductor is vacuum terminated into a beam dump (there is a vacuum gap between cathode and beam dump just like between cathode and anode).

In other embodiments, the present invention concerns a magnetically insulated line oscillator that uses a slatted cathode which transforms the cathode from a solid cylinder like structure (azimuthally continuous) to one that has slats around the edge of the cylinder structure and the slats are capable of providing the necessary current and also introduce additional frequencies (at other than resonant frequencies) making the MILO a multifrequency device.

In other embodiments, the present invention concerns a magnetically insulated line oscillator (MILO) wherein the device controllable meaning that it allows not just for multiple frequencies but that these can be called up or generated as desired and with the users' control—simply by varying the number of slats and the width of the slats.

In other embodiments, the present invention concerns a magnetically insulated line oscillator (MILO) comprising a slatted cathode having slats that fold inside each other mechanically exposing empty spaces or slats with larger azimuthal length.

In other embodiments, the present invention concerns a magnetically insulated line oscillator (MILO) wherein the slats are mechanically controlled from a distance via motors that move the slats in and out.

In other embodiments, the present invention concerns a magnetically insulated line oscillator (MILO) wherein the frequency content, electrical fields, and pulse lengths can be controlled by moving slats into and out of a cylinder surface.

In other embodiments, the present invention concerns a magnetically insulated line oscillator (MILO) wherein a part of the LCR circuit is changed thereby allowing the fundamental frequency of the cavity to be changed.

In other embodiments, the present invention concerns a magnetically insulated line oscillator (MILO) having a cavity and changes to the aperture of the cavity change the capacitance of the cavity.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

FIG. 1 shows a prior art canonical MILO geometry.

FIG. 2 illustrates Pulse and spectral content produced by canonical MILO.

FIG. 3 a cut-away representation of the slatted cathode MILO for an embodiment of the present invention.

FIG. 4A is a side view of the slatted cathodes shown in FIG. 3.

FIG. 4B shows a partially unfolded slat that may be used with an embodiment of the present invention.

FIG. 4C shows a folded slat that may be used with an embodiment of the present invention.

FIG. 4D shows an expandable slat that may be used with an embodiment of the present invention.

FIG. 4E shows a telescoping slat that may be used with an embodiment of the present invention.

FIG. 5 shows the electrical output of a slatted cathode. The configuration shows that under the right circumstances, the output of the slated cathode is the same as that as the solid cathode.

FIG. 6 shows frequency output a slatted cathode geometry and a solid cathode geometry. Notice the shift in frequency as well as the change in spectral content and second harmonic. Additional frequencies are also present near 4 Ghz.

FIG. 7 shows a MILO having a frequency tunable geometry.

FIG. 8 is a particle trajectory plot of a frequency adjustable MILO geometry. The plot also shows the time domain pulse. Notice the cavities, in the slow-wave structure, do not have symmetric size.

FIG. 9 shows the spectral output of 4 different MILO's of the same size using our NOVEL frequency variable control method. The spread is near 400 kHz.

FIGS. 10A and 10B are a composite showing the time-domain pulse of a standard 2.4 Ghz MILO and one with a smaller aperture and one with a larger aperture.

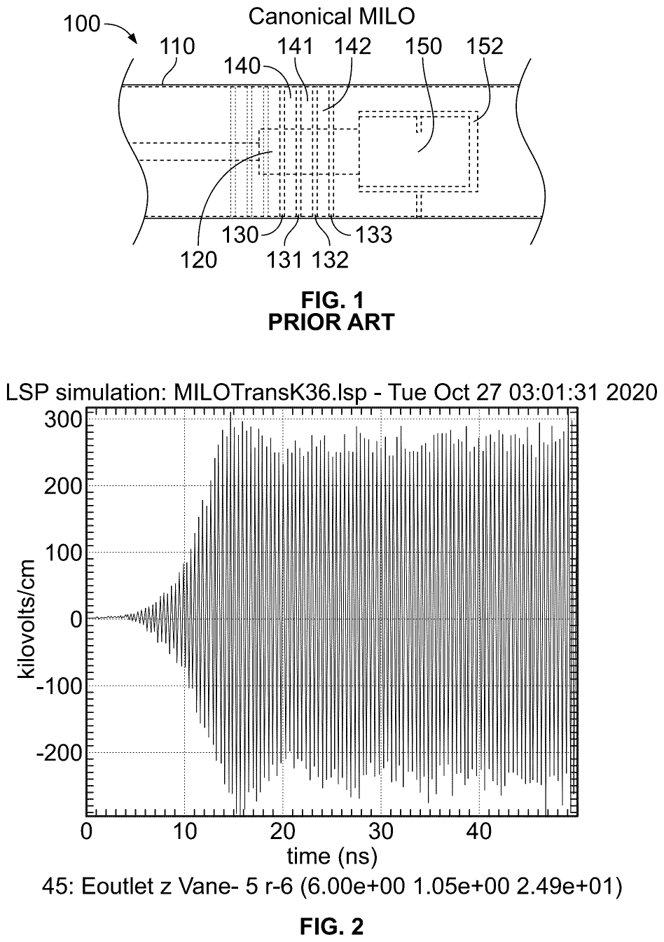

### DETAILED DESCRIPTION OF THE INVENTION

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure, or system. Further, the terms and phrases used herein are not intended to be limiting, but rather to provide an understandable description of the invention.

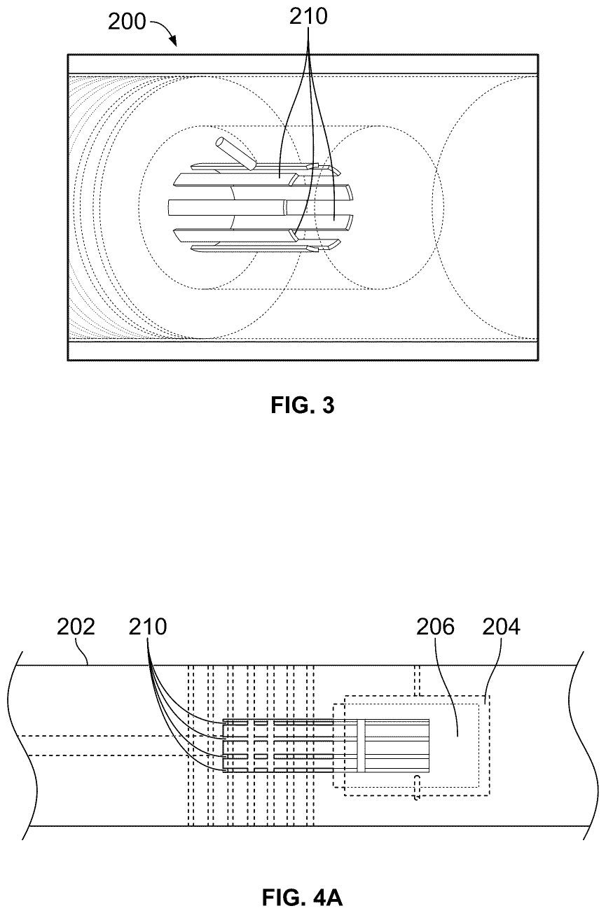

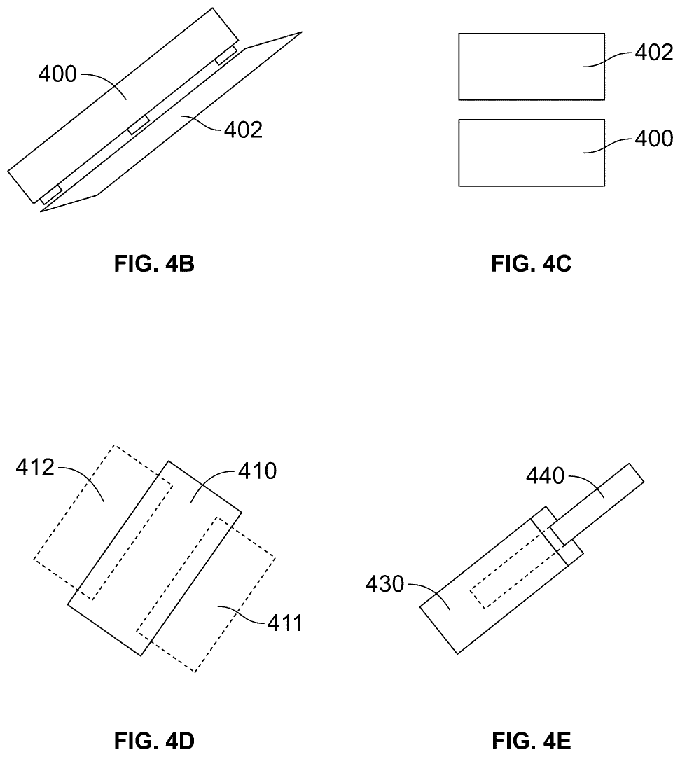

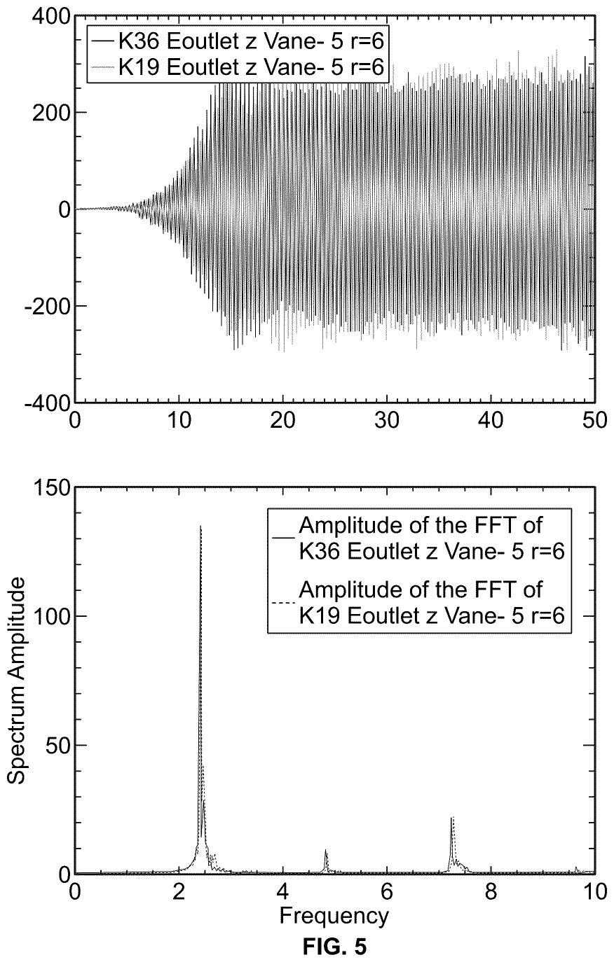

In one embodiment, as shown in FIGS. 3 and 4A, the present invention concerns a device 200 having an anode 202, vacuum 204, beam dump 206 and strips or slats 210 which replace the azimuthally continuous cathode. The slats reduce the number of neutrals because LCR circuit and thereby allowing the fundamental frequency of the slats reduce the surface area. By reducing the surface area by a factor of 2, the neutrals are reduced by a factor of 2. If the surface area of the cathode is reduced then the neutrals are reduced by a factor of 5. The teachings of this embodiment may be used a cross-field device, including MILO's, Magnetrons, Reltrons, TWT, etc. The embodiments of the present invention may also be applied to the electronics in microcircuits.

In other embodiments, as shown in FIGS. 4B and 4C, slatted cathode can be built out of slats 400 and 402 that fold inside each other mechanically exposing empty spaces or slats with larger azimuthal length akin to a window blinds. As shown in FIG. 4D, another way to change the width of a slat is to provide a main slat 410 which includes interior wings 411 and 412 which move in and out of the main slat 410. In yet another embodiment, the azimuthal length of the slat is adjustable by providing telescoping slats 420 and 430. These can be mechanical controlled from a distance via motors that move the slats in and out. Another example would be those street billboards that have multiple images depending on which slats are facing forward. Again these are controlled by motors and computers. In this case depending on the need the frequency content, electrical fields and pulse lengths can be controlled by moving slats into and out of the cylinder surface.

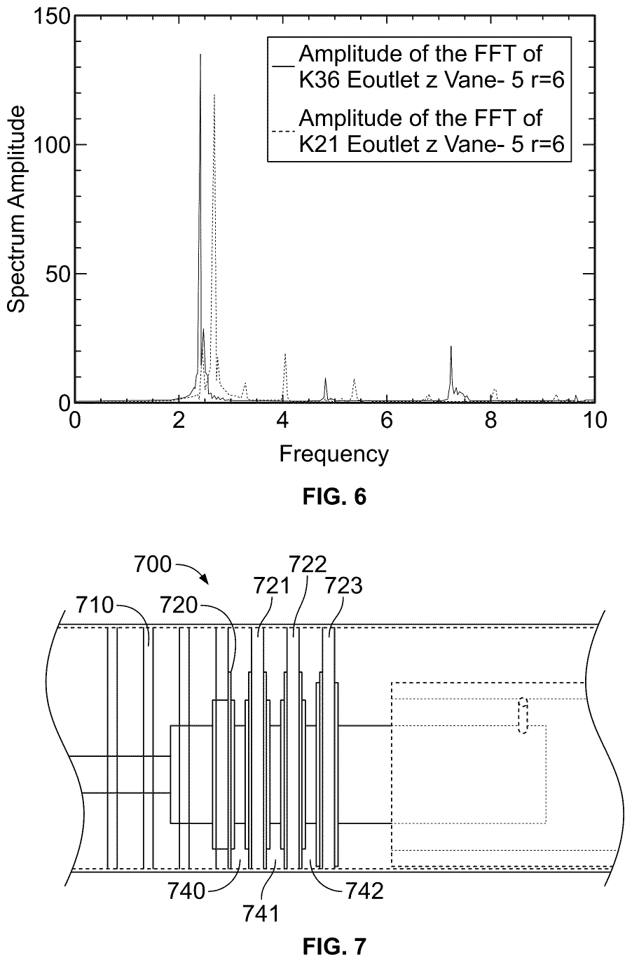

The embodiments of the present invention will increase the pulse length by reducing the surface area and by reducing the number of desorbed neutrals according to that surface area reduction. The slatted cathode is designed to maintain the electrical performance of a full or standard cathode as shown in FIGS. 5 and 6 but it reduces the number of neutrals produced by the cathode and so the pulse length is increased and the pulse repetition rate is improved. In addition, the number of slats can be chosen for the desired operation.

In one embodiment, the present invention uses a slatted cathode which transforms the cathode from a solid cylinder-like structure (azimuthally continuous) to one that has slats around the edge of the cylinder structure. The slats are capable of providing the necessary current and also introduce additional frequencies (at other than resonant frequencies) making the MILO a multifrequency device. It also makes the device controllable meaning that it allows not just for multiple frequencies but that these can be called up or generated as desired and with the users' control—simply by varying the number of slats and the width of the slats.

Reduction of the surface area may be calculated. For a solid cylinder, the surface area is given by

SA=2*Pi*r*L

where Pi is the mathematical constant approximated by 3.1416, r is the radius of a cylinder, L is the length of the cylinder.

Recall that our cathode is cylindrical. For this example, we choose r to be=5 cm and L=20 cm. This gives a surface area for a full cylinder SA=628.32 cm².

For a slatted cathode, the relationship for the surface area of the slatted cathode is

$$S A s c = \frac{Arc Length}{360} * ( 2 * P i * r * L ) * ( \# of Slats )$$

Where arc length is the azimuthal extent of the slat for the canonical example of 9 slats each of arc length of 10 degrees with a radius of 5 cm and length of 20 cm each, SAsc=157.08 cm².

The surface area is reduced by 4. Now for the repetition rate improvement. This repetition rate is governed by the following

$$R e p = \frac{Pressure}{\# neutrals} * ( 7 E 19 \frac{molecules}{liter * torr} ) * Pumping speed of vacuum$$

where #neutrals are the number of molecules desorbed each pulse #neutral is a function of the surface area of a cathode. and if the surface area for a full cathode is 628 cm² and each pulse releases about 3.5E15 molecules/cm\hat{ }2/pulse then #neutrals=2.2 E18.

Pressure=10-6 torr and Pumping speed is 20 liters/sec. This yields a Repetition Rate of 0.000636 Hertz. By reducing the surface area by 4 to ˜157 cm this yields Nneutrals=5.5E17 and a repetition rate of 0.00254 Hertz—an improvement of 4.

In yet other embodiments, the cavity remains the same and only the entrance is changed. This changes the capacitance and the resonant frequency. The invention accomplishes the changes by changing the basic circuit of the cross-field device, including MILO's, Magnetrons, Reltrons, TWT, etc. the embodiments of the present invention may also be applied to the electronics in microcircuits.

In another aspect, the present invention provides a MILO 700 having a frequency tunable geometry as shown in FIG. 7. This embodiment has a modifiable cavity entrance 710 so that the capacitance is changed by altering the entrance or aperture of the cavity. As shown in FIG. 7, one or more spaced apart slow wave blocks or sections 720-723 are adapted to change thickness as desired thereby changing the dimensions of cavities 740-742. In other words, there is an aperture reduction as the thickness of blocks or sections 720-723 increases.

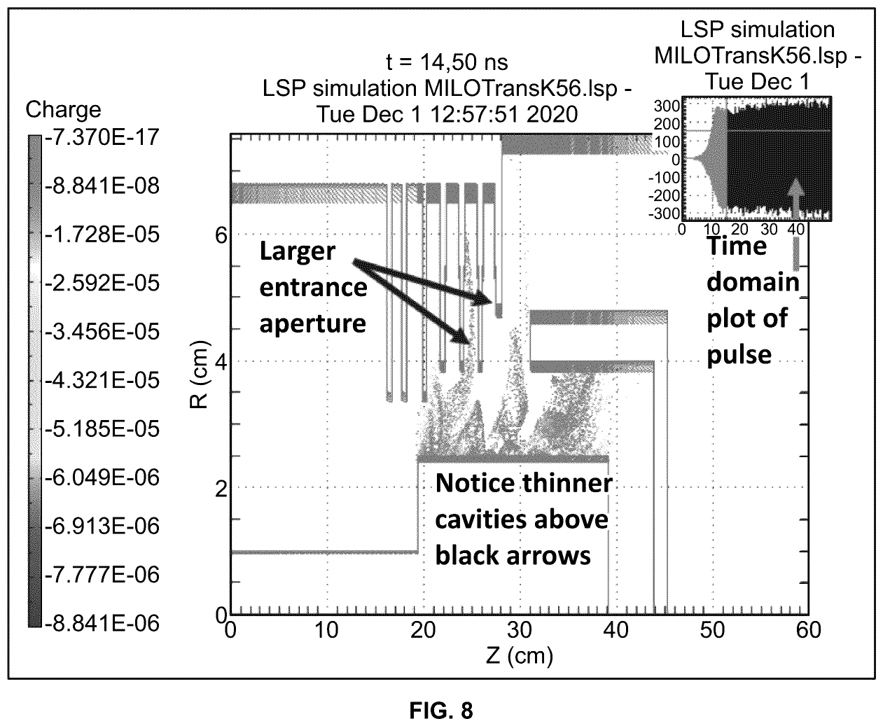

This frequency adjustability/variability/variability may be command controlled. By this, it is meant that a change of the internal geometry via mechanical means can alter the spectral output of a MILO. FIG. 8 shows a particle trajectory plot, in 2 dimensions, as well as the time domain plot of the pulse. This particular geometry increased the aperture entrance.

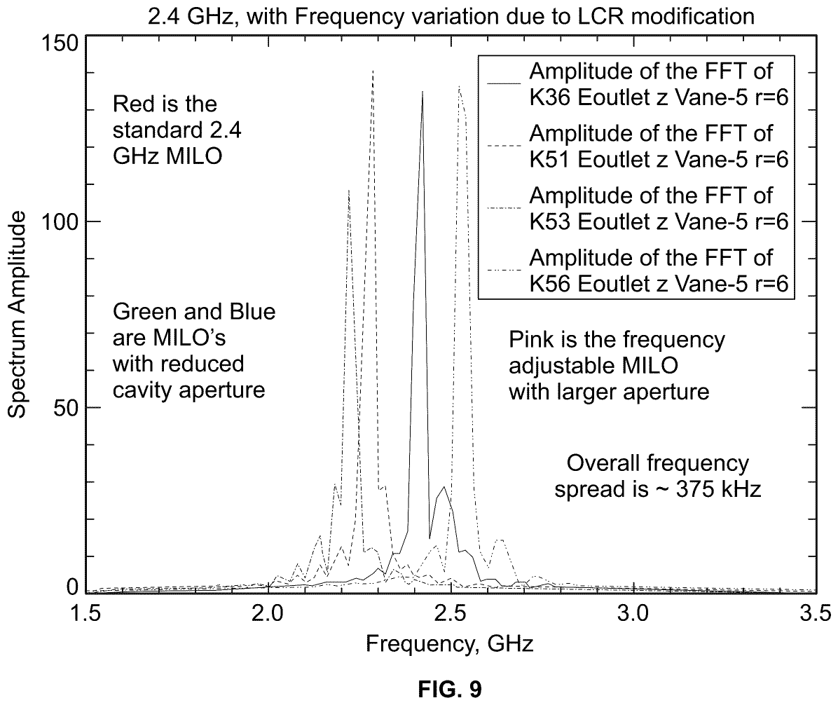

The present invention yields narrowband frequencies just like the canonical device. FIG. 9 shows the FFT of 4 shots, canonical, 2 smaller cavity apertures, and 1 larger aperture. The narrowband spectral content has a controllable spread of approximately 375 kHz which is about 15% of the center frequency.

This is controlled by the size of the aperture. In a larger MILO such as a 1.6 or 1.3 GHz device, 500 kHz variation is expected. Also, notice that this modification ‘cleans’ up the narrow band peak. Notice that a 2.4 GHz contains a small side lobe which is reduced with our method

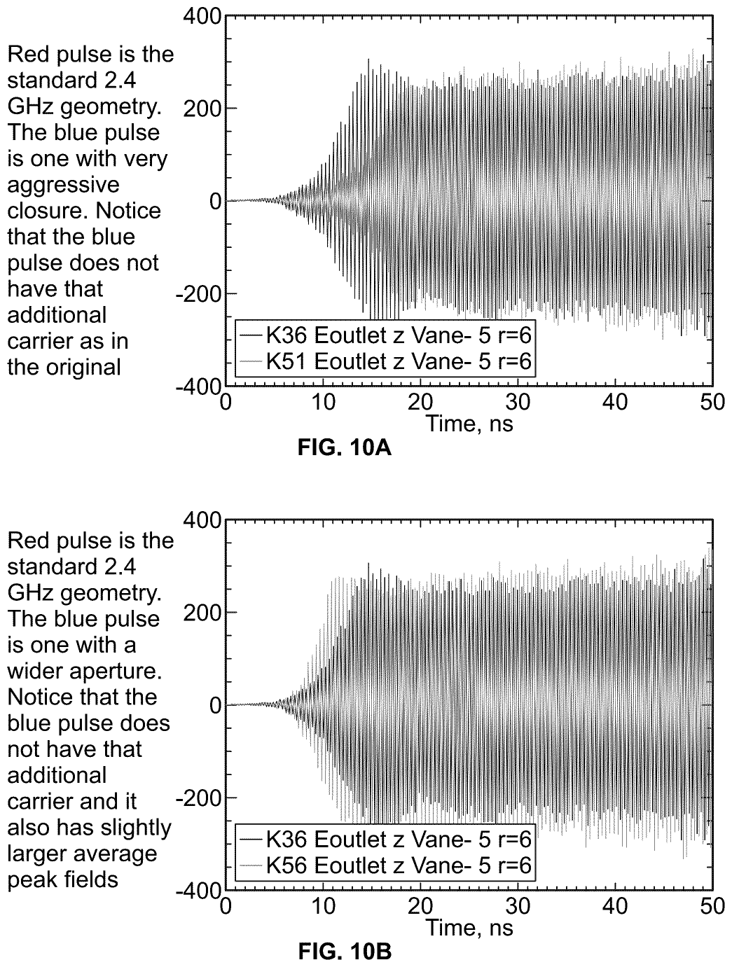

FIG. 10A shows a composite image of two different shots. One with a slightly shorter pulse and one with a longer pulse than the canonical.

In other words, the embodiments of the present invention can also control the pulse startup.

Additionally, the embodiments of the present invention can also increase the peak fields as shown in FIG. 10B.

The embodiments of the present invention not only can change or tune the frequency of the device but also change the start of the pulse and increase field strength

It is important to state that this change in aperture size, either smaller or larger, even deeper into the cavity can be accomplished via mechanical means. In this case, sections 720-723 are each insertable and removeable from cavity 710. In a preferred embodiment, sections 720-723 are disks or vanes. In other embodiments, disks or vanes 720, 722 and 723 may be embedded into a main disk or vane 721 or put back into the main disk or vane (akin to a plastic chair piece that hides the hydraulic steel lift, one piece fits into the other one, and when extended it makes the piece longer. This mechanism can be driven by electrical, hydraulic, or mechanical energy.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above-described embodiments, methods, and examples, but by all embodiments and methods within the scope and spirit of the disclosure.

What is claimed is:

1. A cross field device comprising: an anode and a cathode; said cathode having a plurality of azimuthally extending spaced apart slats.

2. The cross field device of claim 1 wherein the number of said azimuthally extending spaced apart slats is changeable.

3. The cross field device of claim 1 wherein the width said azimuthally extending spaced apart slats is changeable.

4. The cross field device of claim 1 wherein the number of said azimuthally extending spaced apart slats and the width said azimuthally extending spaced apart slats is changeable.

5. The cross field device of claim 1 wherein one or more of said azimuthally extending spaced apart slats fold inside each other.

6. The cross field device of claim 1 wherein the length of one or more of said azimuthally extending spaced apart slats is changeable.

7. The cross field device of claim 1 wherein the space between one or more of said azimuthally extending spaced apart slats is changeable.

8. The cross field device of claim 1 wherein the frequency content, electrical fields, and pulse lengths of said cross field device can be controlled by moving said slats into and out of a cylinder surface.

9. A cross field device comprising: a cavity having an aperture and changes to said aperture of said cavity change the capacitance of the cavity.

10. The cross field device of claim 9 wherein changes to said aperture of said cavity change both the capacitance of said cavity and the fundamental or resonant frequency of said cavity.

11. The cross field device of claim 9 further including one or more spaced apart vanes located in said cavity wherein changing the dimensions of said one or more of said vanes changes the aperture of said cross field device.

12. The cross field device of claim 9 further including one or more spaced apart vanes located in said cavity wherein changing the width of said one or more of said vanes changes the aperture of said cross field device.

13. The cross field device of claim 9 further including one or more spaced apart vanes located in said cavity wherein changing the number of vanes in said cavity changes the aperture of said cross field device.

14. The cross field device of claim 2 wherein said cross field device is a MILO.

15. The cross field device of claim 2 wherein said cross field device is a Magnetron.

16. The cross field device of claim 2 wherein said cross field device is a Reltron.

17. The cross field device of claim 9 wherein said cross field device is a MILO.

18. The cross field device of claim 9 wherein said cross field device is a Magnetron.

19. The cross field device of claim 9 wherein said cross field device is a Reltron.
